(19) United States
(12) Patent Application Publication
(10) Pub. No.: US 2020/0142057 A1
(43) Pub. Date: May 7, 2020

(54) DeepSAR: Specific Absorption Rate (SAR) prediction and management with a neural network approach

(71) Applicant: The Board of Trustees of the Leland Stanford Junior University, Stanford, CA (US)

(72) Inventors: Mihir Pendse, Fremont, CA (US); Brian Rutt, Stanford, CA (US)

(21) Appl. No.: 16/676,046

(22) Filed: Nov. 6, 2019

Related U.S. Application Data
(60) Provisional application No. 62/756,171, filed on Nov. 6, 2018.

(51) Int. Cl. G01S 13/90; G01R 33/563

(52) U.S. Cl. CPC G01S 13/9011; G01R 33/022; G01R 33/56341

(57) ABSTRACT

A DeepSAR method is provided in which local SAR is predicted using a three-dimensional convolutional neural network (CNN). More specifically, a patient-specific local specific absorption rate (SAR) prediction method is provided. A three-dimensional convolutional neural network (CNN) is trained using pairs of SAR maps and B1+ maps for different channel weights. The CNN has an input and an output, and is then provided as a computational device to compute SAR maps. As input to the trained CNN, measured B1+ maps, simulated B1+ maps or a combination thereof are used. The trained CNN then computes and output SAR maps in a form of a generative adversarial network (GAN) to predict a three-dimensional real-valued SAR map with both real and imaginary components to be used for various applications in high field Magnetic Resonance Imaging (MRI).

### CROSS-REFERENCE TO RELATED APPLICATIONS

This application claims priority from U.S. Provisional Patent Application 62/756,171 filed Nov. 6, 2018, which is incorporated herein by reference.

### STATEMENT OF GOVERNMENT SPONSORED SUPPORT

This invention was made with Government support under contract EB025131 awarded by the National Institutes of Health. The Government has certain rights in the invention.

### FIELD OF THE INVENTION

This invention relates to methods, devices and system related to Specific Absorption Rate (SAR) prediction in Magnetic Resonance Imaging (MRI) using neural networks.

### BACKGROUND OF THE INVENTION

Obtaining a robust method of managing local Specific Absorption Rate (SAR) in high field Magnetic Resonance Imaging (MRI) has been challenging. High field MRI has been shown to produce superior image quality, but is limited by radio frequency wavelength effects that result in image inhomogeneities and heating risk for the patient. The pTx pulse has been shown to solve the image inhomogeneity problem reliably, but addressing the heating risk (quantified by SAR) is more challenging because an exact tissue model of the patient for predicting SAR is not available. The present invention addresses this problem.

### SUMMARY OF THE INVENTION

The approach in this invention poses the SAR prediction problem in a deep learning/convolutional neural network framework. Fundamentally, the innovation and advantage of this approach is that it exploits information from an entire population to intelligently infer SAR for a particular patient with improved accuracy compared to prior approaches, most of which have been restricted to using a single tissue model.

In one embodiment, the dataset for training of the neural network pertains of multiple tissue models with a distribution of height, weight, body mass index, and sex that is representative of the target human subject population. On each of these models, electromagnetic simulations with a numerical approximation of the physical transmit coil are performed to produce electric field maps. Using these electric field maps, three-dimensional SAR distributions are computed for each model for several random transmit channel weightings; the SAR matrix formalism is used to make this computation as efficient as possible. For each model, the input to the neural network is the tissue properties for that model has relative permittivity, electrical conductivity, and mass density maps and a particular set of channel weightings. The output is the computed SAR for that model and a set of channel weightings. The entire training set has all combinations of channel weightings and tissue models.

A convolutional neural network architecture is used with multiple filters at each layer including maxpooling layers for downsampling. The channel weightings are input into the network at an intermediate layer and all subsequent layers are fully connected. For a new incoming tissue model, the initial layers that are independent of the channel weights are evaluated. Then the output of these layers as well as the learned weights of the final layers serve as an “oracle” for the IMPULSE optimization algorithm. IMPULSE queries this oracle for the value of SAR and its gradient for several different channel weightings and uses this information to produce a pulse that has minimum predicted SAR on the new tissue model while also satisfying image homogeneity requirements.

This invention can be applied to high field MRI where parallel transmission is necessary to produce a uniform transmit magnetic field. Another application of the method is to decrease local SAR for any MRI system that possesses multi-transmit capability. Embodiments of the invention make parallel transmission clinically viable by providing much greater confidence in SAR prediction than current methods. The method also speeds up SAR prediction and pTx pulse design due to the computational efficiency of convolutional neural networks.

Unlike prior methods that use a single tissue model, which maybe represent a poor approximation of the patient for predicting SAR, the approach of this invention involves the use of an entire population of tissue models. The trained neural network therefore produces more reliable estimates of SAR. Furthermore, with the approach of this invention there is no need for time-consuming electromagnetic simulations to calculate electric fields; this advantage may allow highly accurate SAR prediction to be accomplished in near real time, in other words while the patient is in the scanner.

Embodiments of the invention could be varied, for example, instead of using tissue models as inputs to the convolutional neural network, a possible variation would be to use MR images of the patient as inputs.

In summary, the use of deep learning to predict SAR is new and unique. All prior approaches for solving the SAR-aware parallel transmit problem have relied on the use of a single model for SAR estimation, and no prior method has exploited convolutional neural networks to solve any aspect of this problem. Embodiments of this invention could dramatically improve the practicality of using parallel transmission MRI, and could therefore making this form of MRI clinically feasible by effectively and efficiently managing the risk of tissue heating in the patient. Embodiments of this invention uses deep learning to robustly predict SAR in parallel transmission and is a key step to enabling routine use of ultra-high field MRI in a clinical setting.

In one embodiment, this invention is a DeepSAR method, which predicts local SAR using a three-dimensional convolutional neural network (CNN). In this embodiment, a patient-specific local specific absorption rate (SAR) prediction method is provided. A three-dimensional convolutional neural network (CNN) is trained using pairs of SAR maps and B1+ maps for different channel weights. The CNN has an input and an output, and is then provided as a computational device to compute SAR maps. As input to the trained CNN, measured B1+ maps, simulated B1+ maps or a combination thereof are used. The trained CNN then computes and output SAR maps in a form of a generative adversarial network (GAN) to predict a three-dimensional real-valued SAR map with both real and imaginary components to be used by a high field Magnetic Resonance Imaging (MRI) application for a patient.

Further to this embodiment, the CNN further could have additional computational devices such as a generator (G) and a discriminator (D) network.

In the case of a generator (G) network, the method could input to the generator network the measured B1+ maps, the simulated B1+ maps or the combination thereof, and the method via the generator network could compute and output the SAR maps.

In case of a discriminator (D) network, the method could further input to the discriminator network the SAR maps and the measured B1+ maps, the simulated B1+ maps or the combination thereof, and the method via the discriminator network could compute and output a probability for the SAR maps.

This method of this invention focusing on local SAR prediction using the CNN, a secondary benefit of this invention could be the use of the SAR maps as an improved tool for IMPULSE or other parallel transmit pulse design. As such, the method could further compute a pTx pulse design using the SAR maps computed by the CNN to be applied in high field Magnetic Resonance Imaging (MRI).

### BRIEF DESCRIPTION OF THE DRAWINGS

FIG. 1 shows a conventional approach for patient specific SAR-aware pTx. With a conventional approach it is necessary to first do a localizer scan that is segmented to create a tissue model of the patient. Then a long numerical simulation lasting several hours is done using a numerical model of the coil and the tissue model in order to get simulated B1+ and E fields. In parallel B1+ mapping is done on the scanner and the measured B1+ fields are compared with the simulated B1+ fields to verify similarity and confirm accuracy of the E fields. Then local SAR averaging is performed and SAR matrices are computed for every voxel which is then fed into the pTx pulse design algorithm.

FIG. 2 shows, in contrast to the conventional approach as shown in FIG. 1, the approach of this invention using deep learning wherein only B1+ mapping needs to be performed according to an exemplary embodiment of the invention. The measured B1+ maps then are fed into the neural network with several different channel weights and the SAR matrices are computed through a least-squares fit. This entire process takes under 5 minutes with deep learning compared to several hours with the conventional method as shown in FIG. 1.

FIG. 3 shows according to an exemplary embodiment of the invention input processing (left) and a network diagram. From a database of precomputed simulations, a batch of single-channel B1+ and corresponding SAR matrices is selected. Then a set of random shim weights are generated and used to combine the channels to produce a batch of combined B1+ maps and corresponding combined SAR maps. The B1+ maps are fed into both the generator (G) and discriminator (D) networks. The generator predicts the SAR map from the B1+ map and feeds this into the discriminator along with the true SAR map. The discriminator is evaluated and outputs a loss function with three terms is evaluated. The first term quantifies how well the discriminator differentiates correctly identifies the predicted SAR maps as not genuine. The second term quantifies how well the discriminator correctly identifies the true SAR maps as genuine. The final term further penalizes predicted SAR maps whose peak SAR value is greater than the true peak SAR value since the peak SAR is what contributes to safety risk. The loading and processing of input and the update of the weights is done asynchronously so that even if the batch size is large it doesn't slow down the training.

FIG. 4 shows according to an exemplary embodiment of the invention an architecture of the 3D convolutional GAN. The B1+ maps and SAR maps are both 128×128×128. The generator has an encoder and decoder. The encoder has 3 layers with 5×5×5 kernel and a stride of 2. The final layer in the encoder is a fully connected layer that outputs a vector of codes. The up-convolutional layers also have a 5×5×5 kernel and a stride of 2. The discriminator has 3 layers with a stride of 2 just like the encoder network. The final layer is a fully connected layer with sigmoid activation resulting in a scalar value in the range of 0 to 1.

### DETAILED DESCRIPTION

Ultra-high field (UHF) magnetic resonance imaging (MRI) can result in improved image quality due to increased polarization of nuclear spins which leads to a higher signal to noise ratio compared to conventional methods. However, the electromagnetic wavelength is inversely proportional to the field strength and at UHF, wavelength effects cause complex interactions between the load and the electric and magnetic fields. For different patients, the spatial variations in the fields will be different which requires that the radio frequency (RF) pulse used to excite the magnetic spins be tailored for each specific patient to homogenize the fields. Both the magnetic (B1+) and electric (E) fields are relevant for an MRI scan. Inhomogeneity in the B1+ field leads to image artifacts like shading and central brightening that can negatively impact the interpretability of the image. Inhomogeneity in the E fields can interact with conductive tissue to produce localized heating which constitutes a safety risk for the patient; this heating is characterized by a quantity known as the specific absorption rate (SAR).

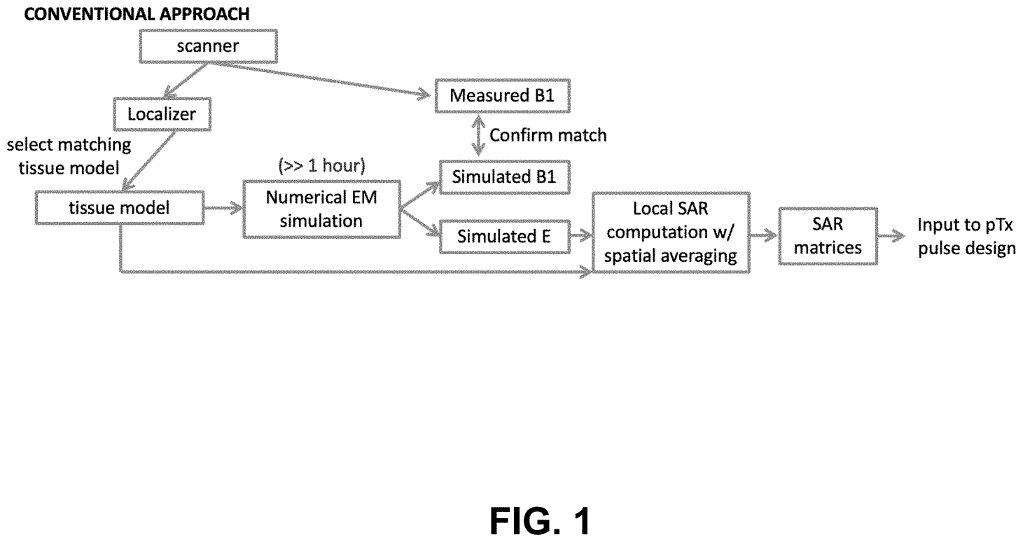

A promising approach for addressing these concerns is to use a parallel transmit (pTx) RF coil which has multiple independent channels that can be excited with different amplitudes and phases such that the combined field is homogeneous. Assuming full knowledge of the B1+ field and the E field, there are established algorithms for finding the RF pulses for each channel of the pTx coil to produce the desired image by eliminating the B1+ inhomogeneity while also ensuring the safety of the patient by eliminating the SAR hotspots through tailoring of the E field. An intermediate step in this process involves precomputing spatially-averaged SAR matrices from the E field which are a convenient formulation that allows finding the SAR distribution for any set of channel weights through a matrix multiplication that takes <100 ms even for up to 10 million total voxels or matrices. The remaining challenge is to find a way to estimate these fields on every subject to feed into the pulse design algorithm. Reliable techniques have been developed, such as the Bloch-Siegert method, to measure the B1+ field in vivo while the patient is in the scanner. However, since MRI is not sensitive to the E component of the field there is no established method for measuring the E fields and there is no obvious way to derive the E field from the B1+ field from first principles. The current method (FIG. 1) for estimating E fields requires doing a simulation with numerical models of the pTx coil to calculate the E field from first principles (i.e. Maxwell's equations). Because this simulation involves stepping through time, calculating the field at every spatial location at every time step until convergence, the duration can be quite long, approaching several hours for a pTx coil even with advanced hardware like GPUs. Furthermore, this simulation requires knowledge of the tissue properties of the patient such as conductivity and permittivity. The process for determining these properties accurately isn't well established and current approaches involve doing a coarse segmentation of an MRI of the patient into a small number of classes and then assigning electric properties to those classes through a lookup table that may not be completely accurate.

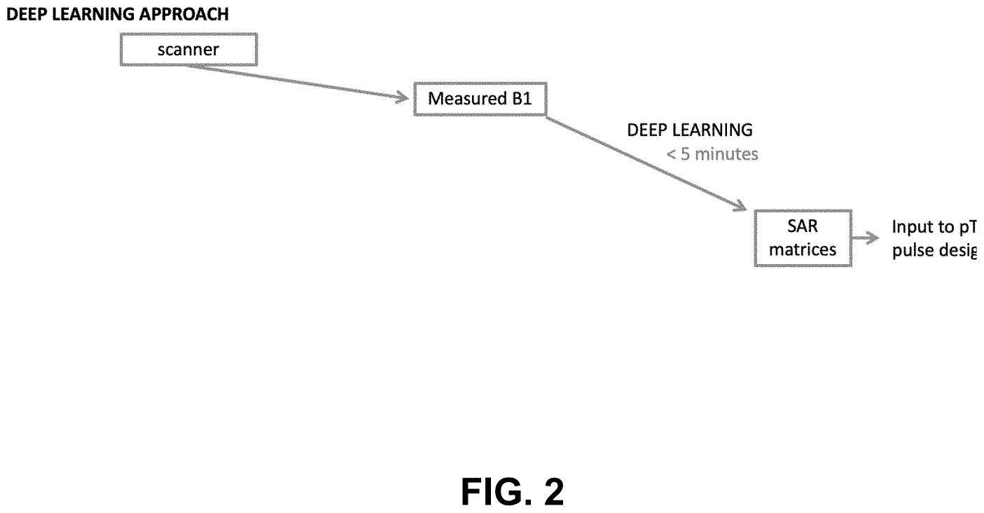

Rather than relying on time-consuming numerical simulation that relies on principles from physics and approximations in the input tissue maps, the proposed method in this invention (FIG. 2) utilizes a deep learning approach to train a Generative Adversarial Network (GAN) to predict the SAR maps from the B1+ maps and then compute the SAR matrices through a least-squares fit by evaluating the network on measured B1+ maps for many random sets of channel weights. The computation time for this approach is under 5 minutes and feasible for a realistic scan unlike the numerical simulations that take several hours. Although deep learning is by nature inexact and unlikely to always give an accurate result, this uncertainty can be managed and isn't significantly more problematic than the conventional approach which also has errors between the model used for simulation and the actual patient.

The deep learning model of this invention has a 3D convolutional neural network, specifically in the form of a Generative Adversarial Network (GAN), to predict a 3D real-valued SAR map from a 3D B1+ map with both the real and imaginary components. The architecture has a generator and a discriminator. The input to the generator is the B1+ map and the output is the SAR map. The input to the discriminator is a SAR map (either the output of the generator or the ground truth SAR map) and the B1+ map and the output is a probability that the SAR map originated from the generator rather than being ground truth (Table 1). The training proceeds in an adversarial manner whereby the generator tries to produce more realistic SAR maps while the discriminator tries to better distinguish the real SAR maps from the generated ones. At convergence, the generated and realistic SAR maps will be indistinguishable to the discriminator. In effect, the discriminator serves as a more sophisticated type of loss function compared to the conventional L1 or L2 loss.

TABLE 1
Inputs and outputs of the generator and discriminator networks.

| Network | Generator | Discriminator |
|---|---|---|
| Input | B1 Map (real and imag) | B1 Map (real and imag) |
| | | and either true |
| | | SAR map or predicted |
| | | SAR map from |
| | | output of generator |
| Output | Generated SAR map | Probability of SAR map being |
| | | consistent with B1 map |

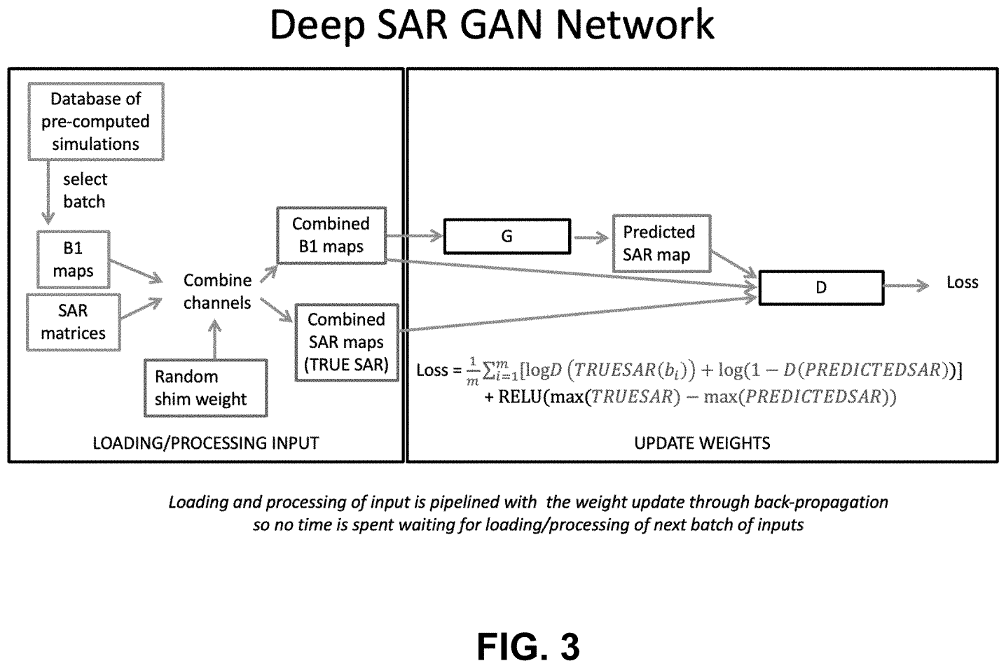

In one example, the training set has pre-simulated B1+ and E fields using a library of numerical head models. These simulations were performed using an 8-channel parallel transmit coil tuned to 298 MHz corresponding to the 7T Larmor frequency. For details, please review to U.S. Provisional Patent Application 62/756,171 filed Nov. 6, 2018, which is incorporated herein by reference, in which the library of head models are shown in Table 2 and the meshing of the simulation including the coil model is shown in FIG. 3. Each model was simulated in 3 different positions (through rigid translation) within the coil to make the training robust to variations in spatial position. The simulation was run by exciting each channel independently and saving the individual channel B1+ maps and the 10 gram spatially averaged SAR matrices.

The neural network predicts combined SAR maps from combined B1+ maps so it requires some channel weighting to combine the maps together. Therefore, during training at each iteration one random simulation from the library is chosen and the corresponding single channel B1+ maps and SAR matrices are loaded (FIG. 3). Then a batch of random channel weights is chosen and normalized so that each vector of weights has the same total power. Then the corresponding combined B1+ maps and SAR maps for each weight vector is computed. These can both be found efficiently through a simple matrix multiplication. At each training iteration a new set of maps from the library and a new set of random channel weights are chosen. The benefit of this architecture is that the neural network learns a direct mapping from B1+ to SAR and doesn't require any knowledge about the coil or patient. In principle, if trained with sufficient data, this approach could perform reliably even on a previously unseen coil model, patient, or region of the body making it a universal approach that can be used on any scanner for any imaging task.

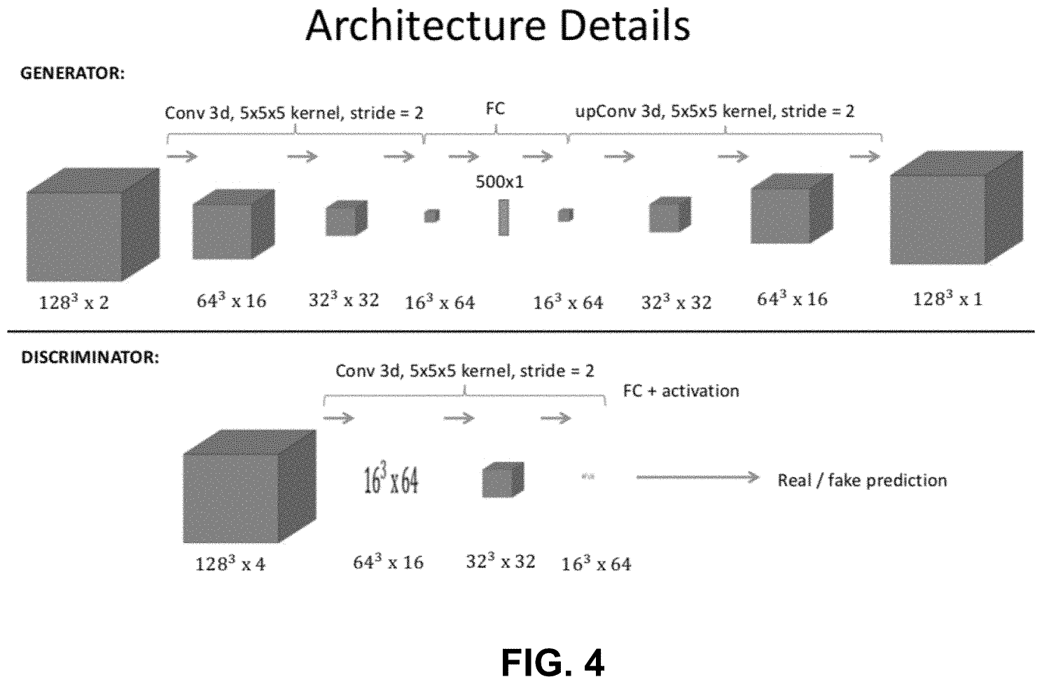

A detailed diagram of the network architecture is shown in FIG. 4. The generator portion of the GAN has an encoder decoder architecture. The encoder takes a 128×128×128 B1+ map and finds a vector whose elements are a compressed representation of the fields. The decoder learns how to convert that compressed representation into the 128×128×128 3D SAR map. The encoder has 3 layers with a 5×5×5 kernel for convolution. A stride of 2 is used in the convolution so that the output of a layer is half that of the input in each dimension. The final layer is fully connected and outputs a 50×1 vector of compressed codes. The encoder is identical to the reverse of the decoder except that it performs up-convolution instead of convolutions so the output is twice the size of the input for each layer. The discriminator architecture is similar to the decoder except it takes both the SAR maps and the B1+ maps as inputs. The final output is a single number representing the probability that the input SAR map is realistic given the input B1+ map.

The training algorithm is described below.

Algorithm 1:

For n iterations do:
For k subiterations do:

| • | Choose m random shim weights b and calculate | |
|---|---|---|
| | corresponding B1 maps (B1(b)), predicted SAR maps by | |
| | evaluating generator (G_{θ}_{_{g}} (B1(b))), and true SAR maps | |
| | from SAR oracle | |
| • | Update parameters θ_{d} of the discriminator network (D) | |
| | through gradient ascent: | |
| | ∘ | ${∇}_{{θ}_{d}} \frac{1}{m} {\sum }_{i = 1}^{m} [ log {D}_{{θ}_{d}} ( TRUE SAR ( {b}_{i} ) , B 1 ( {b}_{i} ) ) +$ |
| | | log (1 − D_{θ}_{_{d}} (PREDICTED SAR(bᵢ), B1(bᵢ)))] + |
| | | RELU(max(TRUE SAR) − |
| | | max (PREDICTED SAR)) |

End for

| | |
|---|---|
| • | Choose m random shim weights b and calculate corresponding |
| | B1 maps (B1(b)) |
| • | Update parameters θ_{g} of the generator network (G) through |
| | gradient ascent: |
| | ${∇}_{{θ}_{g}} \frac{1}{m} {\sum }_{i = 1}^{m} [ log {D}_{{θ}_{d}} ( PREDICTED SAR ( {b}_{i} ) , B 1 ( {b}_{i} ) ) ]$ |

Following the training, the discriminator will be about 50% accurate at correctly identifying the true SAR maps and generated SAR maps. It would be desirable to have a way to estimate the confidence of the SAR prediction. To do this the discriminator is retrained from scratch trying to predict the confidence of the prediction quantified by the error in the peak local SAR, penalizing underestimation more than overestimation.

Once the network is trained, it can be used on any patient, coil, or anatomy taking only the B1+ maps as the input. The pTx pulse design requires SAR matrices, but the neural network only outputs a single SAR map. For this reason, it is necessary to evaluate the network for several different channel weights and use the result to find the SAR matrices using a least-squares fit. The detailed procedure for doing this is as follows:

Algorithm 2:

```
For N iterations do:
  Generate random channel weight vector b_n whose L2 norm is
  equal to 1
  Find combined B1 + map with this channel weighting
  Feed the combined B1 + map into the generator of the trained GAN
  and get the resulting SAR map, S_n
  Evaluate confidence predictor network to estimate w_n, the
  confidence of this SAR prediction
End for
```

Find R using weighted least squares solution to R*B=S (minimize ∥W(RB−S)∥₂)

R has size Nv×Nc\hat{ }2 where each row is a different voxel and each column is each cross term between the elements of the channel weighting vector
B has size Nc\hat{ }2×N corresponding to the cross terms of the N channel weighting vectors
S has size Nv×N and is the vectorized form of the 3D SAR maps for each of the
N channel weights
W has size N×N where the nth element is w_n

Embodiments of the invention could be described as:
1. A patient specific local specific absorption rate pulse design methodology requiring only measured B 1+ maps and no additional scans, simulations, or calibration.
2. An encoder decoder convolutional neural network to predict spatially averaged local SAR maps from real and imaginary components of measured B1+ maps.
   a. Using 3D 5×5×5 convolutional kernel with the entire map as an input.
   b. Using strided convolution instead of maxpooling to reduce the feature size.
3. A loss function found using discriminator network to evaluate quality of the predicted SAR maps instead of a L1 or L2 loss metric.
   a. An additional term in the loss penalizing overestimation of the true peak local SAR
4. A separate confidence predictor network trained after initial training that takes SAR maps and outputs the confidence that the prediction is accurate
5. A weighted least squares optimization to find the SAR matrices to be fed into the parallel transmit pulse design.
   a. Value of SAR to be fit is found by evaluating the trained generator for many random channel weights.
   b. Each example is weighted by its confidence evaluated through the confidence predictor network.

Embodiment of the invention could be methods steps encoded as computer-implemented steps and executed by a computer processor or chip. Embodiments of the invention could be devices such as computer encoded devices, processors or chips. Such embodiments could be part of a system including MRI scanners, equipment, and devices.

What is claimed is:

1. A patient-specific local specific absorption rate (SAR) prediction method, comprising:
(a) having a three-dimensional convolutional neural network (CNN), wherein the CNN is a trained CNN for which training data was used comprising of pairs of SAR maps and B1+ maps for different channel weights, wherein the CNN has an input and an output;
(b) inputting to the trained CNN measured B1+ maps, simulated B1+ maps or a combination thereof; and
(c) computing and outputting SAR maps by the trained CNN in a form of a generative adversarial network (GAN) to predict a three-dimensional real-valued SAR map with both real and imaginary components to be used by a high field Magnetic Resonance Imaging (MRI) application for a patient.

2. The method as set forth in claim 1, wherein the CNN further comprising a generator (G) and a discriminator (D) network.

3. The method as set forth in claim 1, wherein the CNN further comprising a generator (G) network with an input, and wherein the method further comprising inputting to the generator network the measured B1+ maps, the simulated B1+ maps or the combination thereof.

4. The method as set forth in claim 1, wherein the CNN further comprising a generator (G) network with an output, and wherein the method further comprising the generator network computing and outputting the SAR maps.

5. The method as set forth in claim 1, wherein the CNN further comprising a discriminator (D) network with an input, and wherein the method further comprising inputting to the discriminator network the SAR maps and the measured B1+ maps, the simulated B1+ maps or the combination thereof.

6. The method as set forth in claim 1, wherein the CNN further comprising a discriminator (D) network with an output, and wherein the method further comprising the discriminator network computing and outputting a probability for the SAR maps.

7. The method as set forth in claim 1, further comprising computing a pTx pulse design using the SAR maps computed by the CNN to be applied during the high field Magnetic Resonance Imaging (MRI).
